(19) United States
(12) Patent Application Publication
(10) Pub. No.: US 2003/0062921 A1
(43) Pub. Date: Apr. 3, 2003

(54) Bi-directional transmission line termination system

(76) Inventors: David J. C. Johnson, Ft. Collins, CO (US); Jayen J. Desai, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 09/967,188

(22) Filed: Sep. 28, 2001

(51) Int. Cl. H03K 19/003

(52) U.S. Cl. 326/30

(57) ABSTRACT

A first integrated circuit has a driver with the pullup and pulldown devices independently controlled. The output of the driver is connected through an impedance to one end of a transmission line. The other end of the transmission line is connected to a second integrated circuit. The second integrated circuit has a pulldown device connected to the transmission line. The first integrated circuit drives both high logic states and low logic states through the impedance to effect a series termination for communication from the first integrated circuit to the second integrated circuit. The first integrated circuit drives a high logic state through the impedance to effect a parallel termination for communication from the second integrated circuit to the first integrated circuit.

### FIELD OF THE INVENTION

This invention relates generally to the field of electronic integrated circuits and more particularly to the communication of bi-directional digital signals between integrated circuits.

### BACKGROUND OF THE INVENTION

Bi-directional communication of digital signals between integrated circuits (IC's) is fundamental to the operation of modem electronic systems. For example, microprocessor chips may communicate with memory chips; input/output controller chips may communicate with peripheral chips; and, graphics chips may communicate with video ram or a video digital-to-analog converter.

To speed communication between integrated circuits, termination impedances or resistors are often placed at the end of, or in series with, the transmission line or lines connecting the integrated circuits. Often, this may mean that termination resistors exist at both ends of the transmission line or that these resistors be switched into and out-of the circuit depending upon which way data is being transmitted. Furthermore, whenever one chip is driving the line, it induces noise on it's power supplies. To reduce this noise, additional power supplies pins are often added to the chip. This increases cost.

Accordingly, a termination system for bi-directional lines that does not require switching termination impedances on and off and reduces the number of power supply pins is desirable.

### SUMMARY OF THE INVENTION

A first integrated circuit has a driver with the pullup and pulldown devices independently controlled. The output of the driver is connected through an impedance to one end of a transmission line. The other end of the transmission line is connected to a second integrated circuit. The second integrated circuit has a pulldown device connected to the transmission line. The first integrated circuit drives both high logic states and low logic states through the impedance to effect a series termination for communication from the first integrated circuit to the second integrated circuit. The first integrated circuit drives a high logic state through the impedance to effect a parallel termination for communication from the second integrated circuit to the first integrated circuit.

### BRIEF DESCRIPTION OF THE DRAWINGS

FIG. 1 is a schematic illustration of a bi-directional transmission line termination.

FIG. 2 is a table illustrating the states of the control signals and transistors shown in FIG. 1 used to communicate data bi-directionally.

### DETAILED DESCRIPTION OF THE PREFERRED EMBODIMENTS

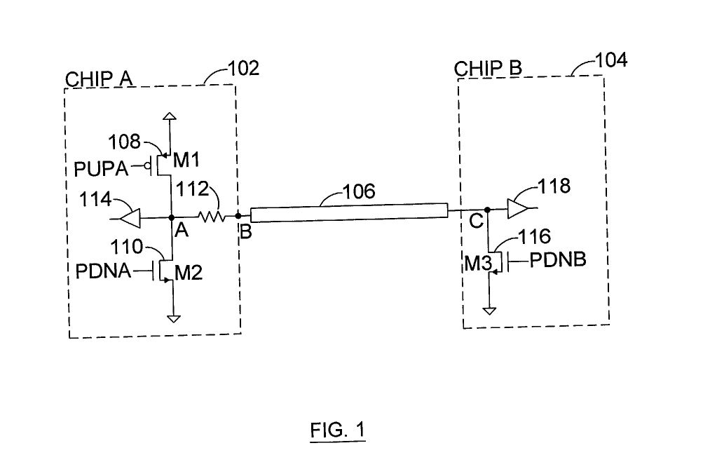

FIG. 1 is a schematic illustration of a bi-directional transmission line termination. In FIG. 1, integrated circuits 102 (chip A) and 104 (chip B) are connected by transmission line 106. The circuitry shown inside integrated circuits 102 and 104 is intended to be representative of one input/output (I/O) pin each and other circuitry and I/O pins may be present inside these integrated circuits and may connect these two integrated circuit and may make connections to other devices or circuits.

Inside integrated circuit 102, the source of p-channel field effect transistor (PFET) 108, M1, is connected to a positive supply voltage. The drain of PFET 108 is connected to node A. The gate of PFET 108 is connected to signal PUPA. The source of n-channel field effect transistor (NFET) 110, M2, connected to a negative supply voltage. The drain of NFET 110 is connected to node A. The gate of NFET 110 is connected to signal PDNA. Also connected to node A is receiver 114 and one end of impedance 112. The other end of impedance 112 is connected to node B. Node B is also connected to a first end of transmission line 106. In FIG. 1, impedance 112 is shown inside of integrated circuit 102. This is for illustrative purposes only and impedance 112 may be internal or external to integrated circuit 102. In one embodiment, impedance 112 is chosen to approximate the characteristic impedance of transmission line 106 and the sizes of M1, M2, and M3 are chosen large enough that their “on” impedance is enough smaller than impedance 112 that it has negligible effects. In another embodiment, the sizes of M1 and M2 are chosen, or adjusted actively to compensate for process, voltage, and temperature variations, to approximate the characteristic impedance of line 106. In this case, since the on impedances of M1 and M2 approximate the characteristic impedance of line 106, a separate impedance 112 is not necessary and may be eliminated.

Inside integrated circuit 104, the source of NFET 116, M3, is connected to a negative supply voltage. The drain of NFET 116 is connected to node C. The gate of NFET 116 is connected to signal PDNB. Also connected to node C is receiver 118 and, external to integrated circuit 104, a second end of transmission line 106.

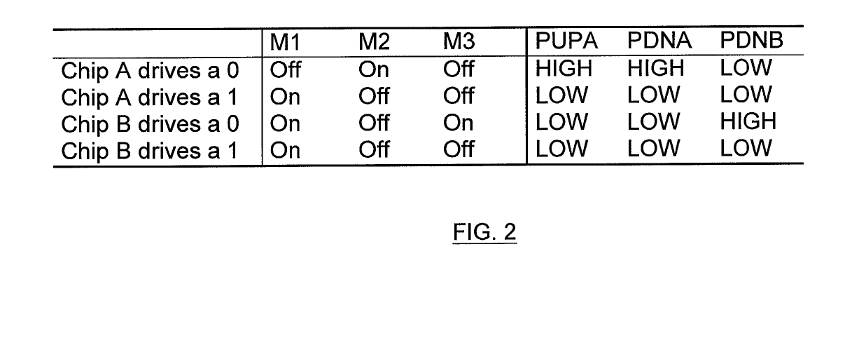

FIG. 2 is a table illustrating the states of the transistors and control signals shown in FIG. 1. For chip A 102 to drive a zero (or low voltage level), M1 is controlled to be off by setting PUPA high, M2 is controlled to be on by setting PDNA high, and M3 is controlled to be off by setting PDNB low. For chip A 102 to drive a zero (or low voltage level), M1 is controlled to be off by setting PUPA high, M2 is controlled to be on by setting PDNA high, and M3 is controlled to be off by setting PDNB low. For chip B 104 to drive a zero, M1 is controlled to be off by setting PUPA high, M2 is controlled to be off by setting PDNA low, and M3 is controlled to be on by setting PDNB high. For chip B 104 to drive a one, M1 is controlled to be off by setting PUPA high, M2 is controlled to be off by setting PDNA low, and M3 is controlled to be off by setting PDNB low.

The configuration and operations shown in FIGS. 1 and 2 eliminate the need for impedance matching at one end of transmission line 106. This reduces system cost and complexity. It also helps reduce cost by eliminating the need for a high-current supply to pullup the bus on the chip B end of transmission line 106. The driver in chip A is series terminated by impedance 116. This allows it to drive signals down transmission line 106 to the open terminated (open because M3 is off) end of transmission line 106 to receiver 118.

When the driver in chip A is not actively driving transmission line 106, it turns on its pullup device (M1). This pulls up transmission line 106 through impedance 112 so that it is effectively parallel terminated when being driven from the chip B end of transmission line 106. Since the line 106 is parallel terminated at the chip A end, the driver at the chip B end of line 106 may be simplified to a simple pulldown device (M3) that does not need impedance matching. To drive a zero from chip B to chip A, the pulldown device in chip B (M3) is turned on. This pulls line 106 down to be received by receiver 114 at the chip A end. To drive a one from chip B to chip A, the pulldown device in chip B (M3) is turned off and the on pullup device (M1) pulls up transmission line 106 through impedance 112 to be received by receiver 114. As can be seen, the driver at the chip B end of line 106 does not need to pull the line up (since this is done by M1 is series with impedance 112). Accordingly, the chip B end of the line does not need to have a special power supply (or introduce noise onto a regular power supply) for pulling up line 106. This reduces the cost of chip B and its packaging.

What is claimed is:

1. A bidirectional communication link, comprising:
a first driver at a first end of a transmission line that is series terminated by a series termination at said first end of said transmission line;
a second driver at a second end of said transmission line that is parallel terminated by said series termination wherein said first driver drives a first logic state through said series termination to effect said parallel termination.

2. The bi-directional communication link of claim 1 wherein said second driver drives a second logic state to send said second logic state from a second device to a first device.

3. The bi-directional communication link of claim 1 wherein said first driver drives a second logic state and said second driver is in a high-impedance state to drive said second logic state from a first device to a second device.

4. The bi-directional communication link of claim 3 wherein said second driver drives said second logic state to send said second logic state from said second device to said first device.

5. A bi-directional communication system, comprising:
a first driver having a first pullup and a first pulldown at a first end of a transmission line;
a second driver having a second pulldown at a second end of said transmission line, and wherein said first pullup is on when said second driver is driving said transmission line.

6. The bi-directional communication system of claim 5 further comprising an impedance disposed between a common node connected to said first pullup and said first pulldown and said first end of said transmission line wherein said impedance approximates the characteristic impedance of said transmission line.

7. The bi-directional communication system of claim 5 wherein said second pulldown is on to drive a first logic state from said second end of said transmission line to said first end of said transmission line and said second pulldown is off to drive a second logic state from said second end of said transmission line to said first end of said transmission line.

8. The bidirectional communication system of claim 7 wherein said first pullup is on and said second pulldown is off to drive said second logic state from said first end of said transmission line to said second end of said transmission line.

9. The bi-directional communication system of claim 8 wherein said first pulldown is on and said second pulldown is off to drive said first logic state from said first end of said transmission line to said second end of said transmission line.

10. Digital communication between a first device and a second device, comprising:
a transmission line connected between said first device and said second device wherein said first device comprises a first pullup and a first pulldown and said second device comprises a second pulldown and wherein said first pullup is on to terminate said transmission line when said communication is going from said second device to said first device.

11. The digital communication of claim 10 wherein said first pullup has an effective impedance that approximates the characteristic impedance of said transmission line.

12. The digital communication of claim 10 wherein said first pullup is connected to a first impedance and said first impedance is connected to said transmission line and said first impedance approximates the characteristic impedance of said transmission line.

13. The digital communication of claim 12 wherein said first impedance terminates said transmission line through said first pullup to a supply voltage when said second device is driving said transmission line.

14. A bi-directional communication link between two IC's, comprising:
a transmission line between a first IC and a second IC;
a first driver on said first IC comprising a first pulldown and a first pullup that drives said transmission line with an impedance that approximates the characteristic impedance of said transmission line when a first logic state is being sent from said first IC to said second IC and when said second IC is sending either a first logic or a second logic state from said second IC to said first IC;
a second driver on said second IC that activates a second pulldown device to send a second logic state from said second IC to said first IC.

15. The bidirectional communication link of claim 14, wherein said first pulldown is activated to send said second logic state from said first IC to said second IC.
